(19) United States
(12) Patent Application Publication
(10) Pub. No.: US 2010/0290047 A1
(43) Pub. Date: Nov. 18, 2010

(54) Image Sensor Device and Method

(75) Inventor: Erez Halahmi, Bazra (IL)

Correspondence Address: The Law Office of Michael E. Kondoudis, 888 16th Street, N.W., Suite 800, Washington, DC, 20006, US

(73) Assignee: NOVATRANS GROUP SA, Vaumarcus Ne (CH)

(21) Appl. No.: 12/678,847

(22) PCT Filed: Sep. 17, 2008
(86) PCT No.: PCT/IL08/01247

§ 371 Date: Jun. 22, 2010

(51) Int. Cl. G01J 3/46; H01L 31/08

(52) U.S. Cl. 356/402; 257/461; 257/E31.052

(57) ABSTRACT

An image sensor cell is presented for detection of electromagnetic radiation. The sensor cell can be used as a pixel in the pixel matrix of an image sensor device. The image sensor cell comprises a photocathode (101), an electrode arrangement (102), and a control unit (16). The electrodes' arrangement is configured for defining multiple spaced apart locations for collecting electrically charged particles emitted from said source of charged particles. The control unit is connected to the electrodes' arrangement and adapted for measuring electrical charge collected at each of said locations, spatial distribution of the collected electrical charge being indicative of profile of electromagnetic radiation causing the emission of said collected charged particles.

### FIELD OF THE INVENTION

The present invention relates to an image sensor device and method.

### BACKGROUND OF THE INVENTION

An image sensor is a device that converts an electromagnetic signal (e.g. visual image) to digital information. It is used chiefly in digital cameras and other imaging devices. The sensor is usually comprised of an array of light sensitive elements or photosensitive cells each presenting an image pixel. Each such cell transforms incident light into an electrical signal which is related to the intensity and/or color of the incident light.

Examples of image sensors include charge-coupled devices (CCDs), CMOS chips, etc. CCDs are commonly used in digital cameras, astronomical telescopes, scanners, and more. A CCD includes an integrated circuit containing an array of coupled light sensitive capacitors. Incident light is converted to electronic charge, which is collected in potential wells, transferred out, detected, and stored. Images are then produced from the stored data. CMOS active pixel sensors (APSs) utilize an integrated circuit containing an array of pixels, where each pixel contains a photo-sensitive element (such as a photodiode) as well as active transistor circuitry for amplification of the pixel's readout signal.

In both the CCD and the APS architectures, the electrical signal generated by each individual pixel corresponds to the intensity of the incident light (luminance). In order to obtain color information (chrominance), the image sensor is equipped with a color filter array, typically with alternating red (R), green (G), and blue (B) filters, for example in the form of the Bayer pattern as disclosed in U.S. Pat. No. 3,971,065. Interpolation methods are used to compensate for the lack of complete color information at each pixel site. Systems, such as a “3CCD system” see for example U.S. Pat. No. 3,975,760; U.S. Pat. No. 4,183,052), employ three separate CCDs at each pixel site, one for each RGB component, and thus obtain both luminance and chrominance data at each pixel. In such a system, incoming light is split using a wavelength selective splitter (dichroic prism or beam splitter) and then split light components of different colors are detected by the corresponding different CCDs. Another known approach for obtaining both the intensity and the color, or spectral composition, of the incident light at each pixel site is to use a multi-layer silicon sensor, as disclosed for example in U.S. Pat. No. 4,581,625, U.S. Pat. No. 4,677,289, U.S. Pat. No. 5,883,421. This technology utilizes the wavelength-dependent absorption coefficient and corresponding light penetration depth of silicon.

### GENERAL DESCRIPTION OF THE INVENTION

The present invention provides a novel photosensitive cell (i.e. pixel element) for use in an image sensor device. The image sensor cell of the present invention is adapted for detecting both the luminance (intensity) and the chrominance (spectral profile) of an electromagnetic radiation. The present invention utilizes the photoemission effect to extract charged particles (electrons) from a source of charged particles, and is based on the motion (propagation scheme) of the charged particle (electrons) emitted in a photoemission process.

In response to electromagnetic (EM) radiation (photons) impinging on a photocathode (constituting a source of charged particles), electrons are emitted having energy and momentum distributions dependent on the spectral distribution of the impinging photons. The inventors of the present invention have found that the electrons' velocities, being indicative of the spectral distribution of the impinging photons, may be measured by utilizing an arrangement of electrodes configured such that electrons emitted at different velocities from the photocathode would be collected at different electrodes (further below referred to as collection electrodes). The electric charge (e.g. the number of electrons) collected by the collection electrodes provides sufficient information regarding the spectral distribution of the impinging electromagnetic radiation and thus enables reconstruction of this spectral distribution. The accuracy of such reconstruction is dependent on several factors including but not limited to the number of electrodes used for collecting the emitted electrons, the type and material of the photocathode and the structure of magnetic and/or electric field, if any, used in the inter space between the electrodes arrangement and the photocathode.

According to a broad aspect of the present invention there is provided an image sensor cell for detection of electromagnetic radiation. The image sensor cell includes a source of charged particles and an electrode arrangement defining multiple spaced apart locations for collecting electrically charged particles emitted from said source of charged particles. The image sensor cell further includes a control unit connected to the electrodes' arrangement and adapted for measuring electrical charge collected at each of the locations defined by the electrode arrangement. The spatial distribution of the collected electrical charge is indicative of the profile of electromagnetic radiation that caused the emission of said collected charged particles.

According to another broad aspect of the present invention there is provided a method for use in determining a spectral profile of light, the method includes (a) directing the light onto a photocathode to thereby cause electrons' emission therefrom and (b) collecting the emitted electrons, propagating in a general direction of propagation from the photocathode, at an array of spaced-apart collection locations arranged such as to collect at different locations electrons having different momenta. The spatial distribution of the collected electrons is indicative of the spectral profile of light.

According to yet another broad aspect of the present invention there is provided an image sensor device for detection and/or imaging of electromagnetic radiation wherein the image sensor device includes an arrangement of pixels (e.g. an array of pixels) each pixel being represented by an image sensor cell of the present invention.

It should be noted that in order to maintain the electrons velocity distribution correlated with the spectral distribution of the detected radiation it is preferable to minimize the interactions (e.g. collisions) of the electrons with any other material particles in their path. It is therefore preferable that a medium within the electrons free propagation space (e.g. in the inter-space between the electrodes arrangement and the photocathode) provides the mean free path of the electrons with respect to a distance between the photocathode and the electrodes arrangement such as to enable a desirably small number of interactions between the electrons and the medium. According to some embodiments of the invention this is achieved by providing vacuum conditions (or sufficiently low pressure conditions) in the space between the photocathode and the collection electrodes to enable collision free propagation of electrons therebetween.

According to some embodiments of the present invention, electrons moving with different velocities/momenta are differentiated utilizing an electric and/or magnetic field(s) spatial profile affecting the trajectories of electrons moving at different velocities such that these electrons are directed towards different collection electrodes.

A correspondence between the frequency of the impinging EM radiation and the energy/momentum distribution of the emitted electrons is dependent on the type and materials of the photocathode used in the sensor cell. More specifically, the kinetic energy Kₘₐₓ of the emitted electrons is determined by the difference between the energy of the impinging photons hv (h being the Planck constant and v the frequency of the photon) and the work function Φ of the photocathode, i.e. Kₘₐₓ(v)=hv−Φ.

It should be noted that the work function of the photocathode is closely related to the occupation of energy levels in the photocathode material.

Theoretically, at zero temperature where the electrons of the photocathode tightly occupy the energy levels of the Fermi sphere, the maximal kinetic energy with which an electron can be emitted is equal to the difference between the photon energy and the material's work function, Kₘₐₓ(v)=hv−Φ. However due to the electrons' thermal energy at temperatures above absolute zero (i.e. where the Fermi sphere is not tightly packed), electrons of energies higher than Kₘₐₓ may be emitted. Nevertheless, for most photocathode materials, also at temperatures above the absolute zero (e.g. room temperatures) the probability of emission of electrons as a result of EM radiation of frequency v is significantly diminished near Kₘₐₓ(v) and decreases rapidly for higher energies. Thus the difference in emission probability between different energy distributions Δ remains narrow also at temperatures above the absolute zero thereby enabling to utilize the electrons' energy distribution to obtain spectral differentiation at the order of A and above (i.e. the enabling to differentiate between impinging photons of energy difference hv₁−hv₂>˜Δ). Kₘₐₓ(v) is in general higher for higher illumination frequencies. However, it should be noted that a correspondence between an electron's kinetic energy and the frequency of an impinging photon does not necessarily hold for any type of photocathode. For instance for certain types of photocathodes, thermalization effects may impair such correspondence and consequently electrons with similar energies may be emitted in response to different frequencies of light. Therefore it is preferable that the photocathode used in the present invention is of the kind for which relatively significant energy-frequency correspondence is maintained during the operation condition (e.g. working temperature) of the sensor cell. To this end metallic photocathodes which maintain such correspondence may be used.

It should also be noted that the type of photocathode used in the sensor cell of the present invention is associated with the range of EM radiation to be detectable by the sensor cell. As mentioned above a photocathode would not emit electrons in response to illumination of energy below the work function of the photocathode. Therefore the work function of the photocathode determines the minimal energy (or maximal wavelength) of photons detectable by the sensor cell. Thus for sensor cells configured for detection of visible light (i.e. 400-700 nm) the work function of the photocathode is such that emission occurs from exposure to the visible spectrum.

Generally according to the present invention, electrons emitted from the photocathode with different energy and momenta are to be directed to different collection electrodes. In some embodiments of the present invention the energies of the impinging photons are estimated by analyzing at least one component of the momentum vectors of the emitted electrons. For example, the longitudinal component of the electrons' momentum, immediately after being emitted from the photocathode, is measured/estimated.

It should be noted that in the following description, the general or average direction of the electrons propagation, immediately after being emitted from the photocathode, is referred to as the longitudinal direction, being practically a direction substantially perpendicular to the emission surface of the photocathode.

The directions substantially perpendicular to such longitudinal direction are referred to as the transverse directions.

It should be understood that although electrons emitted due to impinging radiation of frequency v have a typical kinetic energy K=hv−Φ and corresponding momentum of about P ˜[2mₑ(hv−Φ)]^{1/2} (mₑ being the electrons mass), generally electrons of the same energy might be emitted from the photocathode in different directions and propagate along different trajectories. Such electrons can be identified as corresponding to the same light spectrum based for example on the following considerations:

Generally the conservation of momentum implies that the direction of the emitted electrons is correlated with the direction of the impinging photons. Moreover, the distribution of the longitudinal and transversal components of an electron's momentum (Pₗ and Pₜ respectively) may be broad generally in the range of 0≦(Pₗ, Pₜ)≦[2mₑ(hv−Φ)]^{1/2}, with [2 mₑ(hv−Φ)]^{1/2} being the total momentum. Accordingly the magnitudes of the longitudinal and transversal parts of the electrons momentum for a given photons frequency v are inversely correlated.

The inventors have found that it may be sufficient to measure/estimate at least one component of the electrons momentum by measuring corresponding charge accumulated on collection electrodes, to thereby enable estimation of the spectral distribution of the EM radiation. Thus an arrangement of collection electrodes adapted for separately collecting electrons, emitted with different longitudinal momenta, substantially independently of the electrons transversal momenta components, may be used.

To this end, in the simplest case such an arrangement of collection electrodes may comprise an array of electrodes located along the longitudinal direction such that different electrons having different longitudinal momentum would be captured/collected by different collection electrodes differently distant from the photocathode emission surface. Consequently, indication of the EM spectral distribution may be provided through the distribution of the charge accumulation/collection on the collection electrodes.

However it should be noted that it is not essential to arrange the collection electrodes along the longitudinal direction. Applying magnetic fields and/or electric fields in the region of the electrons propagation may be utilized to bend the trajectory of the electrons propagation, and therefore other arrangements of electrodes may be used to measure one or more components of the electrons momentum.

When utilizing the measurements of the longitudinal part of the electrons momentum as being indicative of the spectrum of the detected electromagnetic radiation (as described above) it may be preferable to control and minimize the effects of the transversal parts of the electrons momentum to enable directing the trajectories of electrons of different longitudinal momentum to be collected at different collection electrodes respectively. Alternatively, an appropriate arrangement of electrodes may be used suitable for separately collecting electrons of different longitudinal velocities/momenta. It should be understood that the electrons, when emitted from the photocathode, have their initial momenta components; an electric field (and/or magnetic field, as the case may be) created within the cell appropriately drives the electrons' movement affecting the longitudinal and transverse components in a manner allowing for distinguishing between electrons of different initial momenta.

Minimizing of the effects of the transversal parts of the electrons momenta may be achieved by utilizing a suitable technique for manipulating the electrons movement to enable minimizing the contributions of the electrons initial transversal momentum to the subsequent movement/trajectory of the electrons, e.g. minimization of ratio between the transversal and longitudinal components of the electrons velocities/momenta.

A first technique may be used by applying an electric or magnetic field adapted to accelerate the electrons in the longitudinal direction thereby decreasing the ratio between the transversal and longitudinal components and minimizing the effect of the transversal momentum component on the subsequent trajectory of the electrons. Alternatively or additionally according to a second technique, an arrangement of one or more focusing electrodes (e.g. ring-like cathode located symmetrically about a portion of electrons' principal direction of propagation) may be used to diminish the transversal part of the electrons' momentum.

As mentioned above, having an appropriate arrangement of electrodes for separately collecting electrons of different longitudinal components enables to measure/estimate the spectral distribution of the impinging EM radiation. Usually, and especially in devices like digital cameras, the incident light is not monochromatic which naturally affects the energy and momentum distribution of the emitted electrons. The most energetic electrons (associated with the highest momenta) will most likely be emitted due to the most energetic component of the incident light. Similarly, every value of electron energy will correspond to some most likely light frequency or spectral component.

The distributions of the electrons' longitudinal momentum components (or equivalently the distribution of the charge accumulation on the collection electrodes) resulting from electromagnetic radiation of different portions of the spectrum (e.g. red, green and blue) may be estimated based on some assumptions. One assumption might be that the multiple directions of the photons impinging on the photocathode are homogeneously distributed within a certain solid angle; such assumption may be imposed by utilizing for example light diffusible coating to scatter photons approaching the absorbance surface of the photocathode thereby “scrambling” any uniform directionality of the photons if such uniform directionality exists. Another assumption may relate to the type/“temperature” of ambient illumination (e.g. day light, tungsten light etc.) which may also affect the expected distributions of the longitudinal momenta components resulting from electromagnetic radiation of different portions of the spectrum.

Nevertheless, utilizing a number of such expected distributions of the longitudinal components of the electrons momenta associated respectively with different parts of the measured electromagnetic spectrum may provide for effective chrominance differentiation by using any known in the art algorithms for matching the data indicative of the accumulation of electric charge on each of the collection electrodes with said expected distributions and obtaining the respective intensities of each of the parts of the electromagnetic spectrum measured.

For example one such algorithm may be based on the fact that although the distribution of the electrons longitudinal momenta components resulting from electromagnetic radiation of certain specific wavelength v (or certain portion of the spectrum) may be broad, e.g. between 0 and P₁^{max}(v), no contribution to the amount of electrons having P₁^{max}(v) would be gained from electromagnetic radiation of frequency lower v. Accordingly, the charge accumulation on the collection electrode associated with the upper part of the measured spectrum (e.g. the blue portion of the spectrum where RGB components of the visible light are measured) would be associated only with impinging electromagnetic radiation of this (e.g. blue) part of the spectrum. However, electromagnetic radiation of this (e.g. blue) part of the spectrum would generally contribute to the accumulation of residual electrical charges (e.g. due to the emission of the electrons of similar momenta in various directions and not only in the longitudinal direction) on collection electrodes associated with electromagnetic radiation of lower frequencies (e.g. the red and green parts of the spectrum). Nevertheless utilizing said expected distributions of the longitudinal components of the electrons momenta enables to estimate the amount of the residual charges accumulated on the other electrodes and to subtract the amount of these residual charges (e.g. associated with the blue portion of the spectra) from the charges collected by the other electrodes. In this manner one may continue to analyze the intensity of the second highest frequency portion of the measured EM radiation (e.g. the green portion) utilizing the fact that no charge is accumulated on the collection electrode associated with this portion due to the lower frequency portion (e.g. red portion) of the impinging electromagnetic radiation and that any charges accumulated are due to the higher frequency portions (e.g. the blue portion) where subtracted as described above. Accordingly this analysis process may be carried out sequentially for lower frequency portions of the measured EM radiation.

It should be noted that for purposes of brevity the above example referred to the visible part of the spectrum and the RGB color scheme was used. However the scope of the present invention may extend beyond the visible part of the spectrum and also utilizing a division of the measured spectrum to a higher number of portions (e.g. by utilizing a greater number of collection electrodes associated with said portions) may provide greater color differentiation.

### BRIEF DESCRIPTION OF THE DRAWINGS

In order to understand the invention and to see how it may be carried out in practice, embodiments will now be described, by way of non-limiting example only, with reference to the accompanying drawings, in which:

FIG. 1 is a block diagram of a sensor cell unit of the present invention;

FIGS. 2A and 2B show two examples respectively of the configuration of the sensor cell unit utilizing an electric field inducing transversal component of the electrons' velocity; and

FIG. 3 shows yet another example of the configuration of the sensor cell of the present invention.

### DETAILED DESCRIPTION OF EXEMPLARY EMBODIMENTS

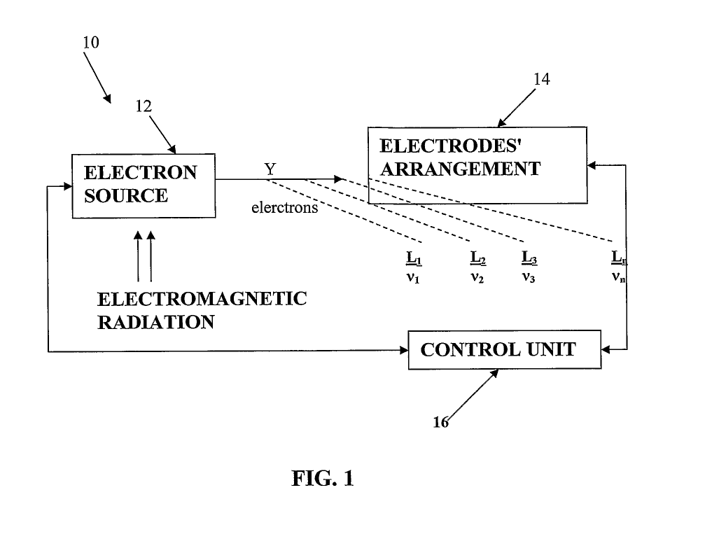

Referring to FIG. 1, there is illustrated, by way of a block diagram, a sensor cell unit 10 according to an embodiment of the present invention. Such a sensor cell unit may be used in an image sensor device, presenting a pixel unit in a pixel matrix. The sensor cell utilizes the principles of photoemission (or thereto-emission) for estimating or measuring the parameters of an external field (incident light) to which the cell is exposed. The device allows for obtaining a spectral profile of the incident multi-frequency light.

Sensor cell 10 includes a source of charged particles 12 and an electrodes' arrangement 14 associated with a control unit 16. It should be understood that generally the present invention may utilize movement of any type of charged particles, but more specifically, it is used with electron beam source and is therefore described below with respect to this specific application.

The electron source includes at least one photocathode which is at least partially exposed to an external electromagnetic radiation (EM) signal that is to be sensed. The photocathode may be any type of photocathode suitable for the purpose of the present invention, namely preserving a statistical correlation between the frequency of the impinging radiation and the energy and/or momentum of the emitted electrons.

The electrodes' arrangement 14 is configured to define a plurality of to spaced-apart collection locations L₁, L₂, . . . Lₙ for collecting electrons. Locations L₁, L₂, . . . Lₙ are spaced at least along one axis, so as to enable collection of electrons of different momenta which correspond to light portions of different parameters, e.g. frequencies f₁, f₂, . . . fₙ, that have caused emission of the respective electrons. As shown in the figure by dashed curves, electrons of different momenta have different trajectories, while all propagating along the general direction. These different trajectories “lead” the respective electrons to different collection electrodes.

As exemplified in FIG. 1, electrons emitted from photocathode propagate along general direction of propagation Y towards the collection electrodes. The electrons' movement is driven by an electric (and possibly also magnetic) field existing in the vicinity of the photocathode allowing the emitted electrons flow away from the photocathode. This may be due to the photocathode electric potential and/or due to the electrodes' arrangement, i.e. a potential difference between the photocathode and one or more other electrodes of the cell. Preferably, the electrodes' arrangement is also configured as an electric field source to provide desired electric field profile. For example, one or more additional electrodes are used.

It should be noted that the sensor cell unit of the invention utilizes electrons' free space propagation through a region (cavity) defined by the electrodes' arrangement. Hence, pressure conditions in a medium within said region are preferably such that the mean free path of the electrons emitted by the photocathode is larger than the inter-electrode distances.

Control unit 16 is configured and operable for “reading” the charge accumulated on each of the collection electrodes, thereby providing data indicative of the light profile of the incident light (e.g. spectral profile). Also, the control unit may include a voltage supply unit connectable to one or more electrodes for providing the desired electric field driving the electrons' movement.

The following are some specific but not limiting examples of the implementation of the sensor cell unit of the present invention.

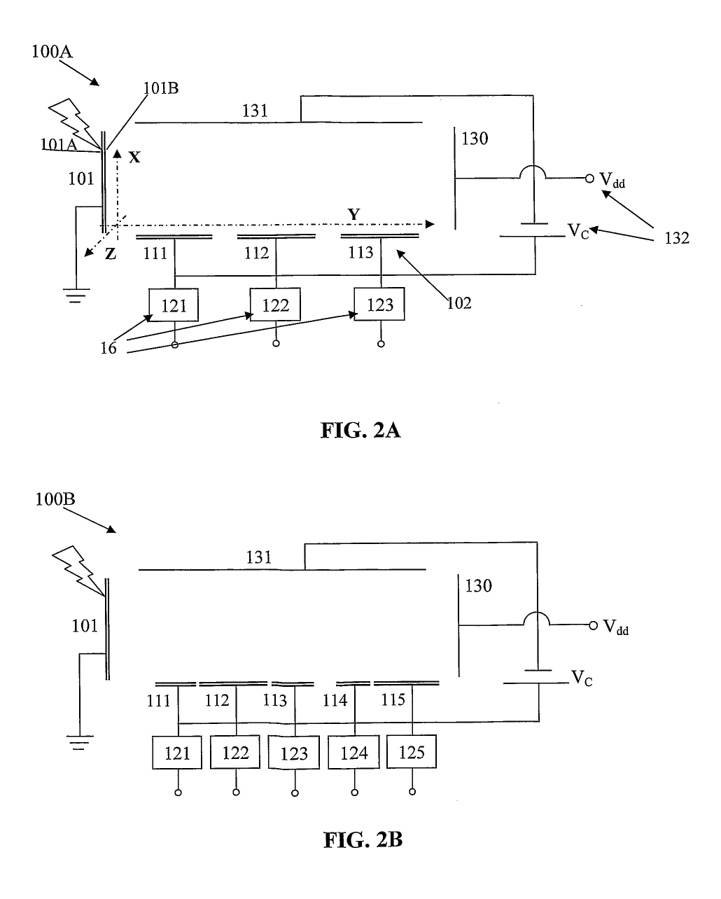

FIG. 2A shows schematically a sensor cell device 100A according to an embodiment of the present invention. The device 100A includes an electron source including a photocathode 101 which comprises an active region 101B from which electrons are emitted when the photocathode is exposed to external illumination (and/or temperature field, as the case may be). In the present example, the photocathode is exposed for back illumination at its surface region 101A, but it should be understood, although not specifically shown, that the same may be achieved by direct illumination of its surface region 101B or by reflection of light from another surface towards the cathode surface region 101B.

The device 100A further includes an electrodes' arrangement configured and operable for collecting electrons on their way from the photocathode. As indicated above, the electrodes' arrangement is configured to define a plurality of spaced-apart locations arranged for collecting electrons propagating along different trajectories, associated with different parameters of light emitted by those electrons. In the present example of FIG. 2A, the electrodes' arrangement includes three collection electrodes 111, 112, and 113 configured for collecting electrons of different kinetic-energy/momentum ranges respectively which are arranged along the general direction of electrons emission Y (hereafter referred to as the longitudinal axis or direction, e.g. substantially perpendicular to the photocathode emission surface 101B). Each of the electrodes 111, 112 and 113 is associated with different portions of light impinging on the photocathode, for example red, green and blue portions of light are associated with the electrodes 111, 112 and 113 respectively. The size and location of each of these electrodes with respect to the photocathode and with respect to each other are designed to enable collection of electrons having different momenta (e.g. associated with different colors) by separate electrodes, thereby enabling estimation/determination of the light parameters. In this example the electrodes associated with more energetic part of the illumination spectrum (accordingly designed for collecting more energetic and fast moving electrons) are located at a farther distance from the emission surface of the photocathode along a general (e.g. average) direction of propagation of the emitted electrons (e.g. along the longitudinal direction).

As indicated above, the electrodes' arrangement may operate as an electric field source by applying an appropriate potential difference between the photocathode and one or more other electrodes of the cell, e.g. an anode electrode 130. For example, the electrons propagation may be driven by voltage supply V_{c} on the collection electrodes 111, 112 and 113 and an opposite side electrode 131, to thereby direct electrons having substantially different momentum in the longitudinal direction towards different collection electrodes. Thus, in the present example, the electrodes' arrangement, formed by collection electrodes 111, 112 and 113 and additional side electrode 131, is configured to provide a first electric field in the transverse direction X (e.g. substantially perpendicular to the longitudinal principal direction of propagation Y) through a potential difference(s) V_{c} between electrode 131 and collection electrodes 111, 112 and 113. Thus, electrons emitted from the photocathode, propagating along the general longitudinal direction Y, are accelerated in the transversal direction X toward the collection electrodes, such that electrons initially emitted with higher component of momentum in the longitudinal direction Y would generally travel a longer distance in this direction before reaching one of the collection electrodes. In this depiction, the V_{c}-related field is spatially constant, but a spatially varying field may be utilized as well, e.g. by applying different voltages on the collection electrodes 111, 112 and 113 or by using additional side electrodes.

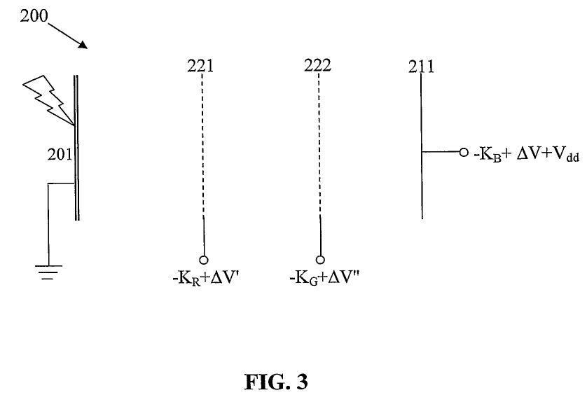

In the above-described example the electrons' trajectories are affected by induced transversal component of the electric field driving the electrons' propagation from the photocathode. It should however be understood that generally, the electrodes' arrangement may be configured so as not to induce such a transversal component at all as will be described further below with reference to FIG. 3.

An electron, immediately after being emitted from the photocathode, is driven from the cathode by initial (extracting) longitudinal and transverse components of its velocity vector. In order to distinguish between electrons having different energies (thus corresponding to different light parameters) the is electric field created in the vicinity of the photocathode and affecting the electrons' movement should preferably minimize the effect of the initial transversal component of the electron's velocity as compared to the longitudinal and transversal components added to the initial ones by the applied field. This can be achieved by inducing relatively strong transverse component as compared to that of the initial velocity vector, and/or inducing relatively strong longitudinal component as compared to the induced and initial transversal ones, and/or reduce the transversal component of the electron's movement by applying a focusing effect.

Thus, turning back to the example of FIG. 2A, the relatively strong induced transversal electric field is utilized, in order to sharpen the electrodes association with different spectral ranges, i.e. potential difference V_{c}. As a result, the transverse velocity distribution of the emitted electrons becomes negligible as compared to the velocity acquired by acceleration in the field. Alternatively or additionally, the present example of FIG. 2A allows for utilizing the effect of anode 130 for providing a second electric field in the longitudinal direction Y, through a potential difference V_{dd} between the photocathode and the anode 130. (In this not limiting example, the photocathode 101 is at ground potential and voltage V_{dd} is applied to the electrode 130). The voltage V_{dd} creates a longitudinal electric field in the direction Y, thus affecting (accelerating or decelerating) the propagation of emitted electrons in the longitudinal direction Y.

It should be understood that the magnitude of the longitudinal electric field may be used to control the required locations of the collection electrodes in accordance with the required spectral range. It should be further understood that acceleration in the longitudinal direction may be used to decrease the effect of the transverse velocity/momentum of the emitted electrons and to increase the spatial distance between electrons having different longitudinal momenta. As indicated above, alternatively or additionally, other electrodes (e.g. focusing electrodes may be used to focus the electron flux along the longitudinal axis to diminish the effect of the transverse velocity distribution of the emitted electrons.

It should be understood that in the above example, the location and size of the collection electrodes along the longitudinal direction and the magnitude of the potential differences V_{c} and V_{dd} determine the spectral ranges, associated with the collection electrodes and detectable by the sensor cell of the above configuration.

An electron emitted from the photocathode 101 with initial kinetic energy Kᵢₙᵢₜ=mv²/2, where the velocity vector v is entirely in the longitudinal direction, is now considered. The electron is accelerated in both the longitudinal and transverse directions, by the V_{dd}- and V_{c}-related fields respectively, but has initial velocity only in the former. The time it takes the electron to reach the plane of the collection electrodes 111, 112, 113 is determined by V_{c}, whereas the longitudinal distance it will cover during this time, and hence which of these electrodes it will reach, is determined also by its initial velocity v. The higher the velocity v is, the farther the electron will travel. The velocity, v, in turn, depends on the energy imparted to the electron by the absorbed photon. The more energetic the illumination, the farther the electron will reach.

The device according to the present invention is designed so that the most energetic electrons, emitted by photons from the “blue” part of the spectrum (approximately 400-475 nm wavelength) reach the farthest collector depicted in FIG. 2A by anode 113. Anode electrode 114 can be used instead of anode 113 using suitable acceleration and inter-electrode distances. In this case, anode 113 may be omitted. The less energetic electrons, most likely emitted by photons from the “green” part of the spectrum (approximately 500-570 nm) are collected by the middle anode 112, and the least energetic, corresponding to the “red” part of the spectrum (approximately 590-650 nm), by the first anode 111. The position and length of each electrode in the longitudinal direction may be adjusted so as to collect electrons corresponding to the desired emission energy range, and therefore to the desired light frequency range. It is possible, furthermore, to distinguish between more than three “ranges” using a larger number of collector anodes.

A control unit 16 is provided. As indicated above, the control unit is configured and operable for measuring charge accumulated on the collection electrodes, and possibly also for creating/controlling an electric field driving the electrons' movement from the photocathode. Thus, in the present example, the control unit 16 includes three charge-storage units (e.g. capacitors) 121, 122 and 123 connected to the electrodes 111, 112, 113 for measurement of the accumulated charge. Also used in the control unit of the example of FIG. 2A is a voltage supply unit 132. The charge-storage units may be capacitors or more complex charge retaining circuitry. Each charges storage unit is electrically connected to its respective collection electrode (anode) in order to allow the charge reaching said electrode to be stored. Each charge storage unit is connected via a switching circuitry (not shown) to a respective external circuitry (not shown) for “reading” the stored charge and processing corresponding data.

To this end, the present example includes two induced electric fields. A first longitudinal electric field (in the longitudinal direction Y) is provided through a potential difference V_{dd} between electrode (anode) 130 and the photocathode. A second transverse electric field is provided through a potential difference V_{c} between side electrode 131 and collection electrodes 111, 112 and 113.

FIG. 2B exemplifies a sensor cell device 100B which is configured generally similar to the above-described device 100A, but in which the electrodes' arrangement includes five collection anodes 111, 112, 113, 114, 115 of different lengths. Accordingly, the control unit includes five corresponding charge-storage units 121, 122, 123, 124, 125.

Reference is made to FIG. 3 showing another exemplary embodiment of a sensor cell device/unit 200 according to the present invention. The device 200 includes an electron source including a photocathode 201, and includes an electrodes' arrangement including collection electrodes 221 and 222 in the form of grids and another collection electrode (anode) 211, arranged in a spaced-apart relationship along the general direction Y and being in the path of electrons propagating from the photocathode. Here, the photocathode is kept at ground potential, and controllable voltages are applied to the anode 211 and the grids 221 and 222. The anode and/or the grids are connected to the control unit (not shown) where further processing of accumulated charge occurs.

When photocathode 201 is exposed to light, electrons are emitted. At this time, a voltage applied to the grid 221 is such that the electrons corresponding to the “red” wavelength range of the incident light (which we henceforth refer to as “red electrons”) cannot cross. This voltage can be expressed as (−K_{R}+ΔV), where K_{R} is the typical emission energy of the red electrons and ΔV is the voltage required to overcome the potential difference between the photocathode and the grid (may be negative), as well as any other measures of compensation such as contact potential difference. In this embodiment, there is only one value of ΔV; which may imply that the grids and the anode are of the same material, but different values may be required. The red electrons lose their kinetic energy upon reaching the grid 221 and are either collected by the grid 221 or held in the region between the photocathode 201 and the grid 221. The more energetic green and blue electrons (i.e. electrons with kinetic energies corresponding to emission by the “green” and “blue” wavelength ranges) continue past grid 221. The voltage applied to the grid 222 is such that the green electrons cannot pass. These are either collected by the grid 222 or held in the region between the grids 221 and 222. The blue electrons, in this embodiment, continue to the anode 211, but a third grid may be included to process or hold these as well.

Processing of the collected charge may be performed as the electrons are emitted and collected by the grids and anode. If processing of the electrons held in the regions between the electrodes is desired, then an “integration procedure” can follow exposure of the photocathode by which the electrons from each region are allowed to reach the anode. For example, the voltage applied to the grid 222 may be raised first so that the green electrons pass and reach the anode 211. This may require adjustment also of the voltage applied to the grid 221. The voltage applied to the grid 221 may then also be raised to allow the red electrons to reach the anode 211 for processing.

Similar to examples of FIGS. 2A and 2B, in the example of FIG. 3 it is also possible to include additional grid(s) for greater spectral resolution. Voltages applied to the grids determine the ranges of energies of the electrons in each region. It is possible to use only collection by the grids without an “integration procedure”, or vice versa, or a combination of these methods.

Thus, the present invention provides a simple and effective technique for an image pixel cell capable of sensing the incident light profile, particularly spectral profile. Those skilled in the art will readily appreciate that various modifications and changes can be applied to the embodiments as hereinbefore exemplified without departing from its scope defined in and by the appended claims.

1. An image sensor cell for detection of electromagnetic radiation, the image sensor cell comprising: a source of charged particles; an electrode arrangement configured for defining multiple spaced apart locations for collecting electrically charged particles emitted from said source of charged particles; and a control unit connected to the electrodes' arrangement and adapted for measuring electrical charge collected at each of said locations, spatial distribution of the collected electrical charge being indicative of profile of electromagnetic radiation causing the emission of said collected charged particles.

2. The image sensor cell of claim 1, wherein the source of charged particles comprises at least one active region adapted for emitting charged particles in response to incident electromagnetic radiation.

3. The image sensor cell of claim 1, wherein said source of charged particles is a photocathode.

4. The image sensor cell of claim 1, wherein said spaced-apart locations are spaced along a first axis substantially parallel to a general direction of propagation of the emitted charged particles from said source of charged particles.

5. The image sensor cell of claim 4, wherein said spaced-apart locations are spaced along a second axis substantially transverse to said second axis.

6. The image sensor cell of claim 4, wherein the electrodes' arrangement comprises an array of electrodes accommodated in a spaced-apart arrangement along at least the first axis.

7. The image sensor cell of claim 1, comprising an electric field source configured and operable for creating an electric field for driving the charged particles' movement from the source of charged particles towards the collection locations.

8. The image sensor cell of claim 6, wherein an arrangement of the collection electrodes and electric potentials on said source of charged particles and on the collection electrodes is selected in accordance with spectral ranges of the electromagnetic radiation to be sensed.

9. The image sensor cell of claim 8, wherein said arrangement of the collection electrodes defines distances between the electrodes, a distance from the source of charged particles for each collection electrodes, and dimensions of the collection electrodes.

10. An image sensor device comprising a pixel arrangement, wherein each pixel is represented by the image sensor cell of claim 1.

11. The image sensor device of claim 10, wherein the source of charged particles is a photocathode unit comprising an array of spaced-apart photocathode active regions.

12. The image sensor device of claim 10, wherein the photocathode unit comprises a continuous photocathode layer associated with a plurality of the sensor cell units.

13. An image sensor cell for detection of electromagnetic radiation, the image sensor cell comprising: an electron source comprising at least one photocathode; an electrode arrangement configured for defining multiple spaced apart locations for collecting electrons emitted from said at least one photocathode; and a control unit connected to the electrodes' arrangement and adapted for measuring electrical charge collected at each of said locations, spatial distribution of the collected electrical charge being indicative of a spectral profile of the electromagnetic radiation that caused the emission of said collected electrons.

14. A method for use in determining a spectral profile of light, the method comprising:
directing the light onto a photocathode to thereby cause electrons' emission therefrom;
collecting the emitted electrons, propagating in a general direction of propagation from the photocathode, at an array of spaced-apart collection locations arranged such as to collect by different locations electrons having different momenta, spatial distribution of the collected electrons being indicative of the spectral profile of light.

15. An image sensor cell for detection of electromagnetic radiation, the image sensor cell comprising: a source of charged particles; an electrode arrangement configured for defining multiple spaced apart locations for collecting electrically charged particles emitted from said source of charged particles, spatial arrangement of the multiple spaced-apart locations corresponding to an energy range of electromagnetic radiation to be sensed; and a control unit connected to the electrodes' arrangement and adapted for measuring electrical charge collected at each of said locations, thereby providing data indicative of spatial distribution of the collected electrical charge being indicative of the profile of electromagnetic radiation causing the emission of said collected charged particles.
